(19) United States
(12) Patent Application Publication
(10) Pub. No.: US 2018/0166645 A1
(43) Pub. Date: Jun. 14, 2018

(54) ORGANIC LIGHT-EMITTING DEVICE AND DISPLAY PANEL

(71) Applicant: Wuhan China Star Oploelectronics Technology Co., Ltd., Wuhan, Hubei (CN)

(72) Inventor: Jinming TANG, Shenzhen, Guangdong (CN)

(73) Assignee: Wuhan China Star Optoelectronics Technology Co., Ltd., Wuhan, Hubei (CN)

(21) Appl. No.: 15/118,866

(22) PCT Filed: Jul. 20, 2016
(86) PCT No.: PCT/CN2016/090600

§ 371 Date: Aug. 13, 2016

(30) Foreign Application Priority Data
Jun. 17, 2016 (CN) 201610437513.8

(51) Int. Cl. H01L 51/50; H01L 27/32; H01L 51/52; H01L 51/56; H01L 51/00; C09K 11/06

(52) U.S. Cl. CPC H01L 51/5024; C09K 2211/1029; H01L 51/5206; H01L 51/5221; H01L 51/5004; H01L 51/5016; H01L 51/5072; H01L 51/56; H01L 51/001; C09K 11/06; H01L 2251/5384; H01L 2251/552; H01L 2251/558; C09K 2211/1018; H01L 51/0072; H01L 51/0067; H01L 51/0085; C09K 2211/185; H01L 27/3244

(57) ABSTRACT

An organic light-emitting device and a display panel are disclosed. The device includes a substrate layer, a first electrode layer, a light-emitting layer, a second electrode layer which are stacked; and a barrier layer disposed between the first electrode layer and the light-emitting layer, or disposed between the second electrode layer and the light-emitting layer, wherein, the barrier layer includes a light-emitting host material, a triplet energy level T1 of the light-emitting host material ≥2.5 ev. Because the organic light-emitting device is disposed with a barrier layer including the light-emitting host material, and the light-emitting host material has a very high triplet energy level T1, when the light-emitting host material is used as the barrier layer, the diffusion of the triplet exciton can be blocked in order to reduce the exciton quenching and increase the lifetime of the organic light-emitting device.

### BACKGROUND OF THE INVENTION

### 1. Field of the Invention

The present invention relates to a display technology field, and more particularly to an organic light-emitting device and a display panel.

### 2. Description of Related Art

Because the AMOLED (abbreviation of active-matrix organic light emitting diode) display panel has advantages of self-luminous, simple structure, low cost, fast response, wide viewing angle, color saturation, high contrast, thin, etc. comparing to an LCD panel so that more and more smartphones and wearable devices begin to adopt the AMOLED panel.

Along with the large-scale application, more and higher requirements for the performance of the AMOLED are proposed such as low voltage, high brightness, high efficiency, low power consumption, long lifetime, etc.

### SUMMARY OF THE INVENTION

The present invention provides an organic light-emitting device and a display panel in order to solve the technology problem of the short lifetime of the AMOLED device in the conventional art.

In order to solve the above technology problem, a technology solution adopted by the present invention is: providing an organic light-emitting device, comprising:

a substrate layer, a first electrode layer, a light-emitting layer, and a second electrode layer which are stacked;

a barrier layer disposed between the first electrode layer and the light-emitting layer, or disposed between the second electrode layer and the light-emitting layer, wherein, the barrier layer includes a light-emitting host material, a triplet energy level T1 of the light-emitting host material ≥2.5 ev;

wherein, the first electrode layer and the second electrode layer are respectively an anode layer and a cathode layer;

wherein, an electron transporting layer is disposed between the barrier layer and the cathode layer, a difference of energy level of lowest unoccupied molecular orbit of the barrier layer and the electron transporting layer is less than 0.2 ev, and a difference of energy level of highest occupied molecular orbit of the barrier layer and the electron transporting layer is greater than 0.2 ev; and

the light-emitting layer is made of a first light-emitting host material and a phosphorescent dopant, and the barrier layer is made of the first light-emitting host material.

Another technology solution adopted by the present invention is: providing an organic light-emitting device, comprising:

a substrate layer, a first electrode layer, a light-emitting layer, and a second electrode layer which are stacked; and

a barrier layer disposed between the first electrode layer and the light-emitting layer, or disposed between the second electrode layer and the light-emitting layer, wherein, the barrier layer includes a light-emitting host material, a triplet energy level T1 of the light-emitting host material ≥2.5 ev.

According to an embodiment of the present invention, the first electrode layer and the second electrode layer are respectively an anode layer and a cathode layer; and

an electron transporting layer is disposed between the barrier layer and the cathode layer, a difference of energy level of lowest unoccupied molecular orbit of the barrier layer and the electron transporting layer is less than 0.2 ev, and a difference of energy level of highest occupied molecular orbit of the barrier layer and the electron transporting layer is greater than 0.2 ev.

According to an embodiment of the present invention, the light-emitting layer is made of a first light-emitting host material and a phosphorescent dopant, and the barrier layer is made of the first light-emitting host material.

According to an embodiment of the present invention, the chemical structural formula of the first light-emitting host material is:

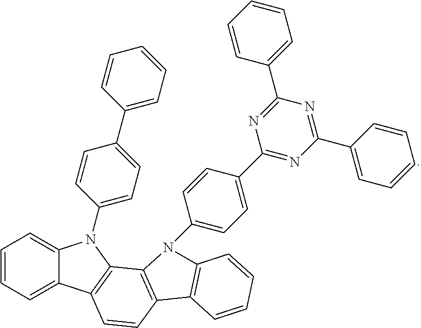 [SMILES: c1ccc(-c2ccc(-n3c4ccccc4c4ccc5c6ccccc6n(-c6ccc(-c7nc(-c8ccccc8)nc(-c8ccccc8)n7)cc6)c5c43)cc2)cc1]

According to an embodiment of the present invention, the chemical structural formula of the first light-emitting host material is:

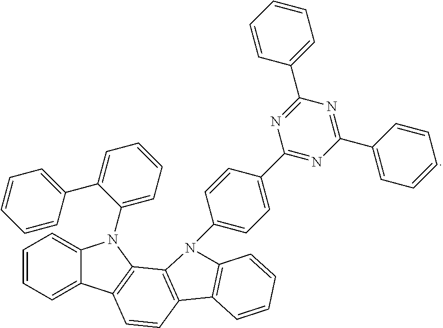 [SMILES: c1ccc(-c2nc(-c3ccccc3)nc(-c3ccc(-n4c5ccccc5c5ccc6c7ccccc7n(-c7ccccc7-c7ccccc7)c6c54)cc3)n2)cc1]

According to an embodiment of the present invention, the chemical structural formula of the first light-emitting host material is:

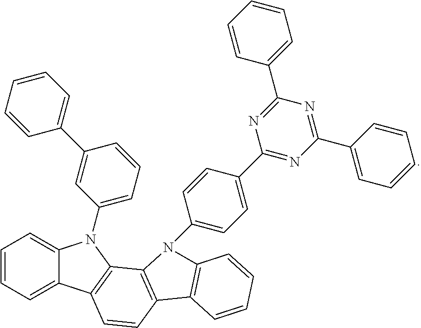 [SMILES: c1ccc(-c2cccc(-n3c4ccccc4c4ccc5c6ccccc6n(-c6ccc(-c7nc(-c8ccccc8)nc(-c8ccccc8)n7)cc6)c5c43)c2)cc1]

According to an embodiment of the present invention, the light-emitting layer is made of a first light-emitting host material, a second light-emitting host material and a phosphorescent dopant, and the barrier layer is made of the first light-emitting host material.

According to an embodiment of the present invention, a ratio of film thicknesses of the first light-emitting host material, the second light-emitting host material and the phosphorescent dopant is 5:5:1.

According to an embodiment of the present invention, the chemical structural formula of the second light-emitting host material is:

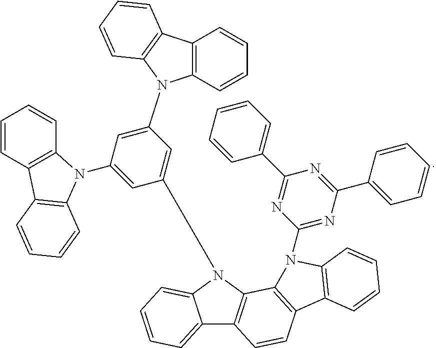 [SMILES: c1ccc(-c2nc(-c3ccccc3)nc(-n3c4ccccc4c4ccc5c6ccccc6n(-c6cc(-n7c8ccccc8c8ccccc87)cc(-n7c8ccccc8c8ccccc87)c6)c5c43)n2)cc1]

According to an embodiment of the present invention, thickness of the barrier layer is in a range of 1 nm˜30 nm.

Another technology solution adopted by the present invention is: providing a display panel, wherein, the display panel comprises a substrate and an organic light-emitting device described above, wherein, the organic light-emitting device is disposed on the substrate, and the organic light-emitting device comprises:

a substrate layer, a first electrode layer, a light-emitting layer, and a second electrode layer which are stacked; and

a barrier layer disposed between the first electrode layer and the light-emitting layer, or disposed between the second electrode layer and the light-emitting layer, wherein, the barrier layer includes a light-emitting host material, a triplet energy level T1 of the light-emitting host material ≥2.5 ev.

The beneficial effect of the present invention is: comparing to the conventional art, because the organic light-emitting device provided by the present invention is disposed with a barrier layer including the light-emitting host material, the light-emitting host material has a very high triplet energy level T1. When the light-emitting host material is used as the barrier layer, the diffusion of the triplet exciton can be blocked in order to reduce the exciton quenching and increase the lifetime of the organic light-emitting device.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures. In the figures:

FIG. 1 is a schematic diagram of an organic light-emitting device of a first embodiment of the present invention;

FIG. 2 is a schematic diagram of an organic light-emitting device of a second embodiment of the present invention;

FIG. 3 is a schematic diagram of an organic light-emitting device of a third embodiment of the present invention;

FIG. 4 is a schematic diagram of an organic light-emitting device of a fourth embodiment of the present invention; and

FIG. 5 is a schematic diagram of a display panel of an embodiment of the present invention.

### DETAILED DESCRIPTION OF THE PREFERRED EMBODIMENT

The following content combines with the drawings and the embodiment for describing the present invention in detail. It is obvious that the following embodiments are only some embodiments of the present invention. For the person of ordinary skill in the art without creative effort, the other embodiments obtained thereby are still covered by the present invention.

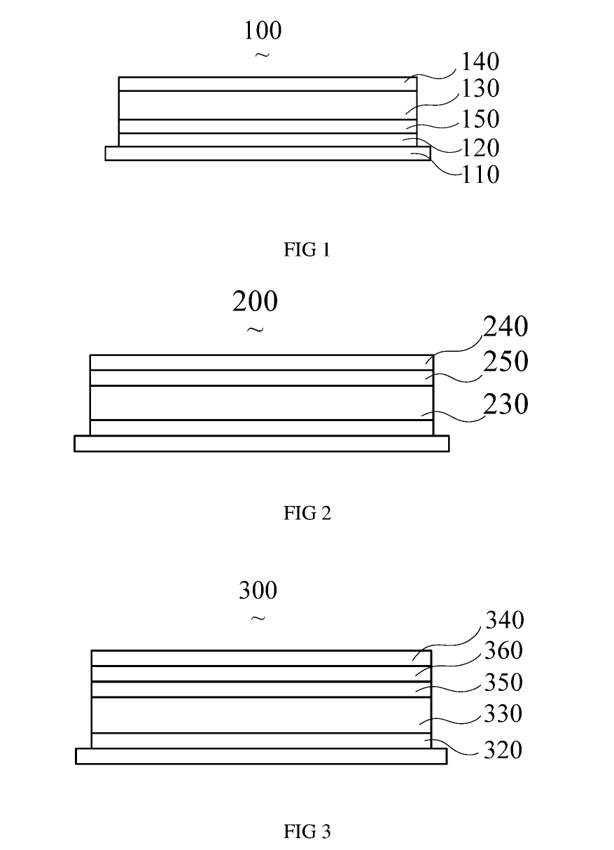

With reference to FIG. 1, and FIG. 1 is a schematic diagram of an organic light-emitting device of a first embodiment of the present invention.

As shown in FIG. 1, the organic light-emitting device 100 includes a substrate layer 110, a first electrode layer 120, a light-emitting layer 130, and a second electrode layer 140 which are stacked. Besides, the organic light-emitting device 100 further includes a barrier layer 150 disposed between the first electrode layer 120 and the light-emitting layer 130. The barrier layer 150 includes a light-emitting host material. A triplet energy level T1 of the light-emitting host material ≥2.5 ev. Wherein, the triplet energy level T1 can maximally reach 3.0 ev or above. Wherein, in a specific application example, the triplet energy level T1 can be 2.8 ev.

The organic light-emitting device 100 provided by the present invention, because the barrier layer 150 including the light-emitting host material is provided, the light-emitting host material has a very high triplet energy level T1. When the light-emitting host material is used as the barrier layer 150, the diffusion of the triplet exciton can be blocked in order to reduce the exciton quenching and increase the lifetime of the organic light-emitting device.

The substrate layer 110 is a transparent substrate, a glass substrate or a flexible substrate. Wherein, the flexible substrate is made of one or multiple materials of polyester compound and polyimide-based compound.

The first electrode layer 120 is an anode layer, and the anode layer 120 can adopt an inorganic material or an organic conductive polymer. Wherein, the inorganic material is metal or metal oxide. The metal is a metal having a higher work function including gold, copper, silver, etc. The metal oxide specifically is indium tin oxide (ITO), zinc oxide, zinc tin oxide, etc. The conductive polymer is one material of polythiophene, polyvinyl benzene sulfonate, and polyaniline.

The second electrode layer 140 is a cathode layer. The cathode layer 140 can adopt metal or metal alloy. Wherein, the metal is a metal that has a lower work function including lithium, magnesium, calcium, strontium, aluminum, zinc, etc. The metal alloy is a metal alloy that has a lower work function or an alloy of the metal alloy and gold, silver or copper. In another embodiment, a cathode layer adopting a metal and a metal fluoride disposed alternatively can be provided. For example, the cathode layer is formed by lithium fluoride, metal silver, lithium fluoride and metal aluminum.

The light-emitting layer 130 is made of a first light-emitting host material and a phosphorescent dopant. The barrier layer 150 is made of the first light-emitting host material.

A thickness of the barrier layer is in a range of 1 nm˜30 nm, or furthermore 5 nm˜10 nm.

### (1) APPLICATION EXAMPLE 1

In the present application example, the first light-emitting host material of the light-emitting layer 130 and the barrier layer 150 of the organic light-emitting device 100 is HOST1, the phosphorescent dopant is a green phosphorescent dopant Dopant1, a percentage of phosphorescent dopant Dopant1 in a film thickness of the light-emitting layer 130 is 10%, wherein, the chemical structural formula of the HOST1 is

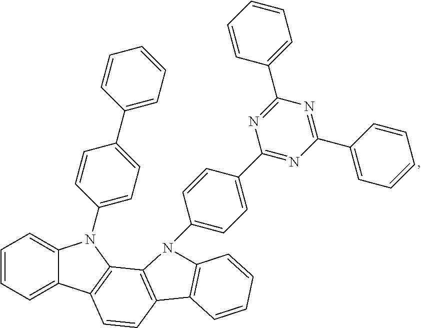 [SMILES: c1ccc(-c2ccc(-n3c4ccccc4c4ccc5c6ccccc6n(-c6ccc(-c7nc(-c8ccccc8)nc(-c8ccccc8)n7)cc6)c5c43)cc2)cc1]

and the chemical structural formula of the Dopant1 is

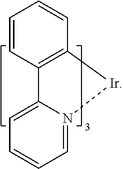

### (2) APPLICATION EXAMPLE 2

The structure of the organic light-emitting device in the present application example is the same as the application example 1, the difference is, the first light-emitting host material is HOST2, wherein, the chemical structural formula of the HOST2 is

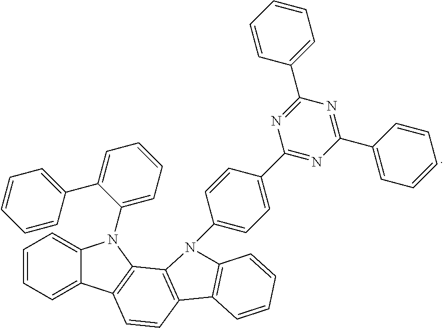 [SMILES: c1ccc(-c2nc(-c3ccccc3)nc(-c3ccc(-n4c5ccccc5c5ccc6c7ccccc7n(-c7ccccc7-c7ccccc7)c6c54)cc3)n2)cc1]

### (3) APPLICATION EXAMPLE 3

The structure of the organic light-emitting device of the present application example is the same as the application example 1, the difference is, the first light-emitting host material is HOST3, wherein, the chemical structural formula of the HOST3 is

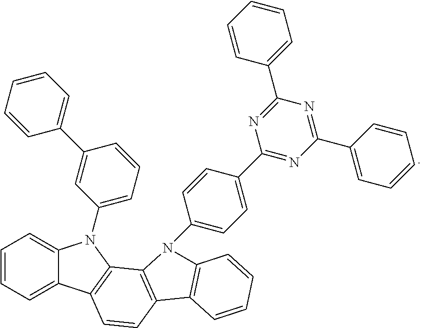 [SMILES: c1ccc(-c2cccc(-n3c4ccccc4c4ccc5c6ccccc6n(-c6ccc(-c7nc(-c8ccccc8)nc(-c8ccccc8)n7)cc6)c5c43)c2)cc1]

The light-emitting layer 130 is made of a first light-emitting host material, a second light-emitting material and a phosphorescent dopant. The barrier layer 150 is made of the first light-emitting host material. Wherein, a ratio of film thicknesses of the first light-emitting host material, the second light-emitting host material and the phosphorescent dopant is 5:5:1.

### (4) APPLICATION EXAMPLE 4

The structure of the present application example is the same as the application example 1, the difference is, in the light-emitting layer 130, a second light-emitting host material is added. The second light-emitting host material is Co-HOST, wherein, a ratio of film thicknesses of the first light-emitting host material HOST1, the second light-emitting host material Co-HOST and the phosphorescent dopant Dopant1 is 5:5:1, wherein, the chemical structural formula of the Co-HOST is

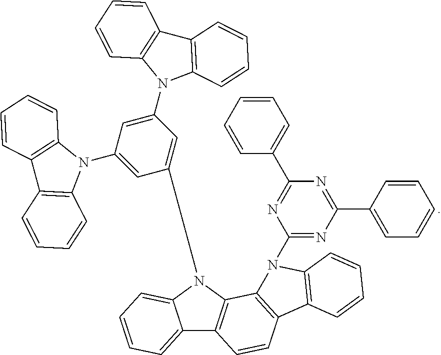 [SMILES: c1ccc(-c2nc(-c3ccccc3)nc(-n3c4ccccc4c4ccc5c6ccccc6n(-c6cc(-n7c8ccccc8c8ccccc87)cc(-n7c8ccccc8c8ccccc87)c6)c5c43)n2)cc1]

### (5) APPLICATION EXAMPLE 5

The structure of the organic light-emitting device of the present application example is the same as the application example 4, the difference is, the first light-emitting host material is HOST2.

### (6) APPLICATION EXAMPLE 6

The structure of the organic light-emitting device of the present application example is the same as the application example 4, the difference is, the first light-emitting host material is HOST3.

In another application example, a barrier layer 150 without the first light-emitting host material can be adopted.

Parameters of the energy level and the mobility of the first light-emitting host material and the second light-emitting host material are shown in Table. 1

TABLE.1
parameters of the energy level and the mobility of the first
light-emitting host material and the second light-emitting host material

| | | | | | Hole | Electron |
|---|---|---|---|---|---|---|
| | HOMO/ | LUMO/ | | | mobility | mobility |
| Material | ev | ev | S1/ev | T1/ev | cm2/Vs | cm2/Vs |
| HOST1 | −5.9 | −2.7 | 3.2 | 2.8 | 3 * 10−5 | 7.1 * 10−5 |
| HOST2 | −5.8 | −2.7 | 3.1 | 2.7 | 2.4 * 10−5 | 7.3 * 10−5 |
| HOST3 | −5.8 | −2.7 | 3.1 | 2.7 | 3.4 * 10−5 | 7.4 * 10−5 |
| Co-HOST | −5.5 | −2.8 | 2.7 | 2.5 | 5.4 * 10−5 | 6.8 * 10−5 |

Wherein, HOMO (abbreviation of Highest Occupied Molecular Orbital) is the highest occupied molecular orbit, LUMO (abbreviation of Lowest Unoccupied Molecular Orbital) is the lowest unoccupied molecular orbit. Singlet energy level S1 is a difference value of the energy level of the lowest unoccupied molecular orbit (LUMO) and the energy level of the highest occupied molecular orbit (HOMO).

From the data shown in the Table. 1 each of the first light-emitting host material and the second light-emitting host material has a good bipolar property which is beneficial to the injection and recombination of the electron and the hole such that a recombination area of the exciton is wide so as to improve the lifetime of the organic light-emitting device. Besides, each of the first light-emitting host material and the second light-emitting host material has a very high triplet energy level T1, and when functions as a barrier layer, the diffusion of the triplet exciton can be blocked in order to reduce the exciton quenching and increase the life of the organic light-emitting device.

With reference to FIG. 2, in the present embodiment, a barrier layer 250 of the organic light-emitting device 200 is disposed between a second electrode layer 240 and a light-emitting layer 230.

With reference to FIG. 3, and FIG. 3 is a schematic diagram of an organic light-emitting device of a third embodiment of the present invention.

A first electrode layer 320 and a second electrode layer 340 are respectively an anode layer and a cathode layer; furthermore including an electron transporting layer 360 disposed between the barrier layer 350 and the cathode layer 340, and a difference of energy level of lowest unoccupied molecular orbit (LUMO) of the barrier layer 350 and the electron transporting layer 360 is less than 0.2 ev, a difference of energy level of highest occupied molecular orbit (HOMO) of the barrier layer 350 and the electron transporting layer 360 is greater than 0.2 ev.

In the organic light-emitting device of the present invention, a substrate layer, an anode layer, a light-emitting layer, a cathode layer and a barrier layer are necessary layers, however, except the necessary layers, a hole injecting and transporting layer and an electron injecting and transporting layer can be provided. Wherein, the hole injecting and transporting layer means anyone or both of a hole injecting layer and a hole transporting layer, and the electron injecting and transporting layer means anyone or both of the electron injecting layer or the electron transporting layer.

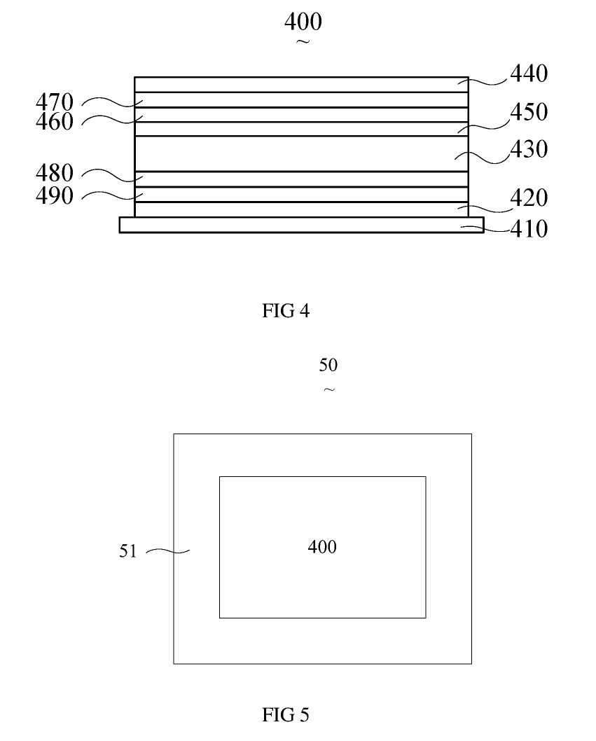

With reference to FIG. 4, an organic light-emitting device 400 is a specific embodiment, the structure of the organic light-emitting device can refer to the organic light-emitting device 400.

The organic light-emitting device 400 includes a substrate layer 410, an anode layer 420, a hole injecting layer 490, a hole transporting layer 480, a light-emitting layer 430, a barrier layer 450, an electron transporting layer 460, an electron injecting layer 470 and a cathode layer 440.

### (7) APPLICATION EXAMPLE 7

The substrate layer 410 adopts a glass substrate, the anode layer 420 adopts indium tin oxide (ITO), the hole injecting layer 490 adopts a material of HAT(CN)6, the hole transporting layer 480 adopts a material of HTM081 manufactured by the merck company, the light-emitting layer 430 adopts the first light-emitting host material HOST1 and the phosphorescent dopant Dopant1, the barrier layer 450 adopts the first light-emitting host material HOST1, the electron transporting layer 460 adopts a material of BPhen, the electron injecting layer 470 adopts LiF, and the cathode layer 440 adopts aluminum.

Wherein, the chemical structural formula of HAT(CN)6 is

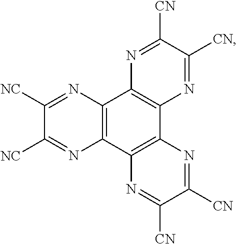 [SMILES: N#Cc1nc2c3nc(C#N)c(C#N)nc3c3nc(C#N)c(C#N)nc3c2nc1C#N]

the specific composition of HTM081 is a trade secret of the merck company. The chemical structural formula of BPhen is

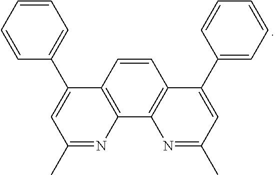 [SMILES: Cc1cc(-c2ccccc2)c2ccc3c(-c4ccccc4)cc(C)nc3c2n1]

The main manufacturing method for the organic light-emitting device 400 is the evaporation method, and the manufacturing process comprises:

Step 1: Cleaning the Substrate Layer 410 and the Anode Layer 420

Performing an ultrasonic cleaning to the glass substrate 410 coated with ITO in a detergent. Then, washing in the deionized water. Performing an ultrasonic cleaning in a mixed solvent of a volume ratio of acetone to ethanol be 1:1. Baking in a clean environment, wherein, a baking temperature is in a range of 130° C.˜220° C. and a time period is from one hour to two hours. Cleaning by using ultraviolet light and ozone. Then, using a low energy cation beam to bombard a surface of the ITO such that the ITO of the glass substrate 410 forms the anode layer 420.

Step 2: Evaporating Other Layers

Placing the glass substrate 410 coated with ITO in a vacuum chamber. Evacuating to 1×10⁻⁶ Pa˜2×10⁻⁴ Pa. On an anode surface of the ITO, evaporating HAT(CN)6 as a hole injecting layer 490. Wherein, an evaporation rate is in a range of 0.01 nm/s˜0.1 nm/s, an evaporation thickness is in a range of 1 nm˜10 nm. In the present application example, the evaporation rate adopts 0.05 nm/s and the evaporation thickness adopts 5 nm.

Evaporating HTM081 on a surface of the hole injecting layer 490 as a hole transporting layer 480. Wherein, the evaporation rate is in a range of 0.01 nm/s˜0.2 nm/s, an evaporation thickness is in a range of 10 nm˜30 nm. In the present application example, the evaporation rate adopts 0.1 nm/s and the evaporation thickness adopts 20 nm.

Evaporating the first light-emitting host material HOST1 and the phosphorescent dopant Dopant1 as a light-emitting layer 430. A percentage of phosphorescent dopant Dopant1 in a film thickness of the light-emitting layer 430 is 10%. Wherein, a double-source co-evaporation method is adopted to evaporate the first light-emitting host material HOST1 and the phosphorescent dopant Dopant1. Wherein, an evaporation rate of the first light-emitting host material HOST1 is in a range of 0.05 nm/s˜0.5 nm/s, an evaporation rate of the phosphorescent dopant Dopant1 is in a range of 0.005 nm/s˜0.05 nm/s, a total evaporation thickness is in a range of 10 nm˜50 nm, the thicknesses of the materials are proportionally distributed according to the evaporation rates. In the present application, the evaporation rate of the first light-emitting host material HOST1 adopts 0.1 nm/s, the evaporation rate of the phosphorescent dopant Dopant1 adopts 0.01 nm/s and the total evaporation thickness adopts 30 nm.

Evaporating the first light-emitting host material on a surface of the light-emitting layer 430 as a barrier layer 450, wherein, the evaporation rate is in a range of 0.01 nm/s˜0.2 nm/s, an evaporation thickness is in a range of 1 nm˜10 nm. In the present application example, the evaporation rate adopts 0.1 nm/s and the evaporation thickness adopts 5 nm.

Evaporating Bphen on a surface of the barrier layer 450 as an electron transporting layer 460. Wherein, the evaporation rate is in a range of 0.01 nm/s˜0.2 nm/s, an evaporation thickness is in a range of 10 nm˜30 nm. In the present application example, the evaporation rate adopts 0.1 nm/s and the evaporation thickness adopts 20 nm.

Evaporating lithium fluoride on a surface of the electron transporting layer 460 as an electron injecting layer 470. Wherein, the evaporation rate is in a range of 0.005 nm/s˜0.1 nm/s, an evaporation thickness is in a range of 0.1 nm˜5 nm. In the present application example, the evaporation rate adopts 0.01 nm/s and the evaporation thickness adopts 0.5 nm.

Evaporating aluminum on a surface of the electron injecting layer 470 as a cathode layer 440. Wherein, the evaporation rate is in a range of 0.005 nm/s˜0.5 nm/s, an evaporation thickness is in a range of 100 nm˜200 nm. In the present application example, the evaporation rate adopts 0.1 nm/s and the evaporation thickness adopts 150 nm. The thickness of the cathode layer 440 is far greater than the thickness of the other layers because the cathode layer 440 is required to reach a total reflection condition.

The evaporation process of the above layers can be at different vacuum chambers, each vacuum chamber is evacuated to 1×10⁻⁶ Pa to 2×10⁻⁴ Pa.

### (8) APPLICATION EXAMPLE 8

The evaporation rate and thickness of the present application example is the same as the application example 7, the difference is, the first light-emitting host material HOST1 of the light-emitting layer 430 and the barrier layer 450 is replaced as the first light-emitting host material HOST2.

### (9) APPLICATION EXAMPLE 9

The evaporation rate and thickness of the present application example is the same as the application example 7, the difference is, the first light-emitting host material HOST1 of the light-emitting layer 430 and the barrier layer 450 is replaced as the first light-emitting host material HOST3.

### (10) APPLICATION EXAMPLE 10

The evaporation rate and thickness of the present application example is the same as the application example 7, the difference is, the first light-emitting host material HOST1 of the light-emitting layer 430 is replaced as the first light-emitting host material HOST1 and the second light-emitting host material Co-HOST.

Specifically, evaporating the first light-emitting host HOST1, the second light-emitting host material Co-HOST and the phosphorescent dopant Dopant1 as the light-emitting layer 430. Wherein, a ratio of film thicknesses of the first light-emitting host material, the second light-emitting host material and the phosphorescent dopant is 5:5:1. A tri-source co-evaporation method is adopted to evaporate the first light-emitting host material HOST1, the second light-emitting host material Co-HOST and the phosphorescent dopant Dopant1. Wherein, an evaporation rate of the first light-emitting host material HOST1 is in a range of 0.05 nm/s˜0.5 nm/s, an evaporation rate of the second light-emitting host material Co-HOST is in a range of 0.05 nm/s˜0.5 nm/s, an evaporation rate of the phosphorescent dopant Dopant1 is in a range of 0.005 nm/s˜0.05 nm/s. A total evaporation thickness is in a range of 10 nm˜50 nm. The thicknesses of the materials are proportionally distributed according to the evaporation rates. In the present application, the evaporation rate of the first light-emitting host material HOST1 adopts 0.1 nm/s, the evaporation rate of the second light-emitting host material Co-HOST adopts 0.1 nm/s, the evaporation rate of the phosphorescent dopant Dopant1 adopts 0.02 nm/s and the total evaporation thickness adopts 30 nm.

### (11) APPLICATION EXAMPLE 11

The evaporation rate and thickness of the present application example is the same as the application example 10, the difference is, the first light-emitting host material HOST1 of the light-emitting layer 430 and the barrier layer 450 is replaced as the first light-emitting host material HOST2.

### (12) APPLICATION EXAMPLE 12

The evaporation rate and thickness of the present application example is the same as the application example 10, the difference is, the first light-emitting host material HOST1 of the light-emitting layer 430 and the barrier layer 450 is replaced as the first light-emitting host material HOST3.

### (13) COMPARISON EXAMPLE 1

The evaporation rate and thickness of the present application example is the same as the application example 7, the difference is, the barrier layer 450 made of the first light-emitting host material HOST1 is not adopted.

Performance parameters of the organic light-emitting device 400 obtained in each application example and the comparison example are shown as Table. 2

TABLE 2
performance parameters of the organic light-emitting device

| | | | Current | Color | |
|---|---|---|---|---|---|
| | Brightness | Voltage | efficiency | coordinates | Lifetime |
| Device | cd/m² | V | cd/A | (x, y) | LT90 |
| Comparison | 5000 | 4.0 | 45.3 | (0.32, 0.61) | 100 |
| example 1 | | | | | |
| Application | 5000 | 3.8 | 46.7 | (0.32, 0.61) | 200 |
| example 7 | | | | | |
| Application | 5000 | 3.8 | 46.9 | (0.32, 0.61) | 230 |
| example 8 | | | | | |
| Application | 5000 | 3.9 | 47.2 | (0.32, 0.61) | 245 |
| example 9 | | | | | |
| Application | 5000 | 4.2 | 47.3 | (0.32, 0.61) | 410 |
| example 10 | | | | | |
| Application | 5000 | 4.1 | 47.7 | (0.32, 0.61) | 420 |
| example 11 | | | | | |
| Application | 5000 | 4.3 | 48.4 | (0.32, 0.61) | 450 |
| example 12 | | | | | |

From the data shown in Table. 2, using the color coordinates (0.32, 0.61) as a reference, comparing among the application example 7, the application example 8, the application example 9 and the comparison example 1 (without the barrier layer 450), the voltage and the current efficiency are basically the same, and the lifetime of the organic light-emitting device 400 is extended to be double. The reason is that the first light-emitting host material has a very high triplet energy level, when the light-emitting host material is used as the barrier layer 450, the diffusion of the triplet exciton can be blocked in order to reduce the exciton quenching and increase the lifetime of the organic light-emitting device 400. Comparing among the application example 10, the application example 11, the application example 12 and the comparison example 1, when adopting the first light-emitting host material and the second light-emitting host material, the recombination area of the exciton are further improved in order to increase the lifetime of the organic light-emitting device 400, wherein, the lifetime of the organic light-emitting device is extended to be double.

With reference to FIG. 5, and FIG. 5 is a schematic diagram of a display panel of an embodiment of the present invention.

As shown in FIG. 5, the display panel 50 includes a substrate 51 and the organic light-emitting device 400 described above. Wherein, the organic light-emitting device 400 is disposed on the substrate 51.

Wherein, the structure of the organic light-emitting device 400 can refer to the content of the above, no more repeating.

In summary, the person skilled in the art can easily understood, because the organic light-emitting device provided by the present invention is disposed with a barrier layer including the light-emitting host material, the light-emitting host material has a very high triplet energy level T1. When the light-emitting host material is used as the barrier layer, the diffusion of the triplet exciton can be blocked in order to reduce the exciton quenching and increase the lifetime of the organic light-emitting device.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. An organic light-emitting device, comprising:
a substrate layer, a first electrode layer, a light-emitting layer, and a second electrode layer which are stacked;
a barrier layer disposed between the first electrode layer and the light-emitting layer, or disposed between the second electrode layer and the light-emitting layer, wherein, the barrier layer includes a light-emitting host material, a triplet energy level T1 of the light-emitting host material ≥2.5 ev;
wherein, the first electrode layer and the second electrode layer are respectively an anode layer and a cathode layer;
wherein, an electron transporting layer is disposed between the barrier layer and the cathode layer, a difference of energy level of lowest unoccupied molecular orbit of the barrier layer and the electron transporting layer is less than 0.2 ev, and a difference of energy level of highest occupied molecular orbit of the barrier layer and the electron transporting layer is greater than 0.2 ev; and
the light-emitting layer is made of a first light-emitting host material and a phosphorescent dopant, and the barrier layer is made of the first light-emitting host material.

2. An organic light-emitting device, comprising:
a substrate layer, a first electrode layer, a light-emitting layer, and a second electrode layer which are stacked; and
a barrier layer disposed between the first electrode layer and the light-emitting layer, or disposed between the second electrode layer and the light-emitting layer, wherein, the barrier layer includes a light-emitting host material, a triplet energy level T1 of the light-emitting host material ≥2.5 ev.

3. The device according to claim 2, wherein,
the first electrode layer and the second electrode layer are respectively an anode layer and a cathode layer; and
an electron transporting layer is disposed between the barrier layer and the cathode layer, a difference of energy level of lowest unoccupied molecular orbit of the barrier layer and the electron transporting layer is less than 0.2 ev, and a difference of energy level of highest occupied molecular orbit of the barrier layer and the electron transporting layer is greater than 0.2 ev.

4. The device according to claim 2, wherein, the light-emitting layer is made of a first light-emitting host material and a phosphorescent dopant, and the barrier layer is made of the first light-emitting host material.

5. The device according to claim 2, wherein, the chemical structural formula of the first light-emitting host material is:

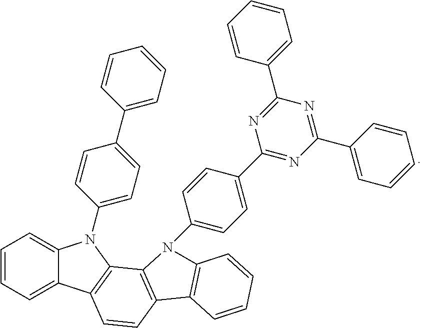 [SMILES: c1ccc(-c2ccc(-n3c4ccccc4c4ccc5c6ccccc6n(-c6ccc(-c7nc(-c8ccccc8)nc(-c8ccccc8)n7)cc6)c5c43)cc2)cc1]

6. The device according to claim 4, wherein, the chemical structural formula of the first light-emitting host material is:

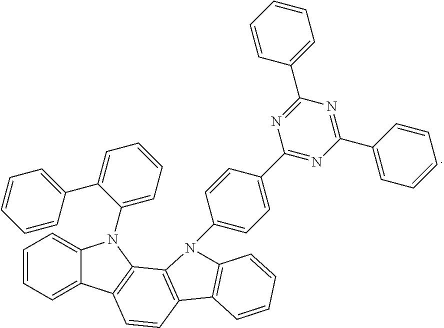 [SMILES: c1ccc(-c2nc(-c3ccccc3)nc(-c3ccc(-n4c5ccccc5c5ccc6c7ccccc7n(-c7ccccc7-c7ccccc7)c6c54)cc3)n2)cc1]

7. The device according to claim 4, wherein, the chemical structural formula of the first light-emitting host material is:

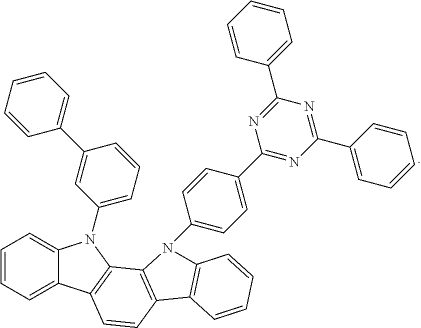 [SMILES: c1ccc(-c2cccc(-n3c4ccccc4c4ccc5c6ccccc6n(-c6ccc(-c7nc(-c8ccccc8)nc(-c8ccccc8)n7)cc6)c5c43)c2)cc1]

8. The device according to claim 2, wherein, the light-emitting layer is made of a first light-emitting host material, a second light-emitting host material and a phosphorescent dopant, and the barrier layer is made of the first light-emitting host material.

9. The device according to claim 8, wherein, a ratio of film thicknesses of the first light-emitting host material, the second light-emitting host material and the phosphorescent dopant is 5:5:1.

10. The device according to claim 8, wherein, the chemical structural formula of the second light-emitting host material is:

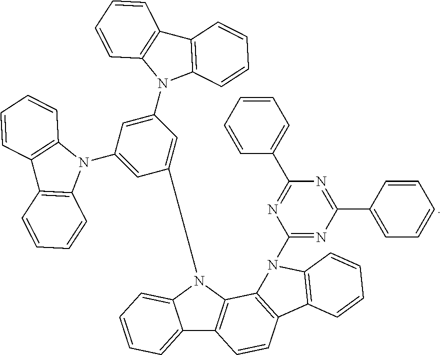 [SMILES: c1ccc(-c2nc(-c3ccccc3)nc(-n3c4ccccc4c4ccc5c6ccccc6n(-c6cc(-n7c8ccccc8c8ccccc87)cc(-n7c8ccccc8c8ccccc87)c6)c5c43)n2)cc1]

11. The device according to claim 2, wherein, a thickness of the barrier layer is in a range of 1 nm˜30 nm.

12. A display panel, wherein, the display panel comprises a substrate and an organic light-emitting device, wherein, the organic light-emitting device is disposed on the substrate, and the organic light-emitting device comprises:
a substrate layer, a first electrode layer, a light-emitting layer, and a second electrode layer which are stacked; and
a barrier layer disposed between the first electrode layer and the light-emitting layer, or disposed between the second electrode layer and the light-emitting layer, wherein, the barrier layer includes a light-emitting host material, a triplet energy level T1 of the light-emitting host material ≥2.5 ev.

13. The display panel according to claim 12, wherein,
the first electrode layer and the second electrode layer are respectively an anode layer and a cathode layer; and
an electron transporting layer is disposed between the barrier layer and the cathode layer, a difference of energy level of lowest unoccupied molecular orbit of the barrier layer and the electron transporting layer is less than 0.2 ev, and a difference of energy level of highest occupied molecular orbit of the barrier layer and the electron transporting layer is greater than 0.2 ev.

14. The display panel according to claim 12, wherein, the light-emitting layer is made of a first light-emitting host material and a phosphorescent dopant, and the barrier layer is made of the first light-emitting host material.

15. The display panel according to claim 14, wherein, the chemical structural formula of the first light-emitting host material is:

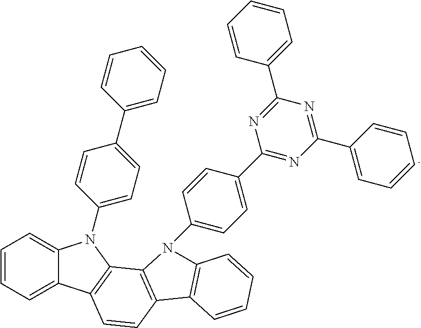 [SMILES: c1ccc(-c2ccc(-n3c4ccccc4c4ccc5c6ccccc6n(-c6ccc(-c7nc(-c8ccccc8)nc(-c8ccccc8)n7)cc6)c5c43)cc2)cc1]

16. The display panel according to claim 14, wherein, the chemical structural formula of the first light-emitting host material is:

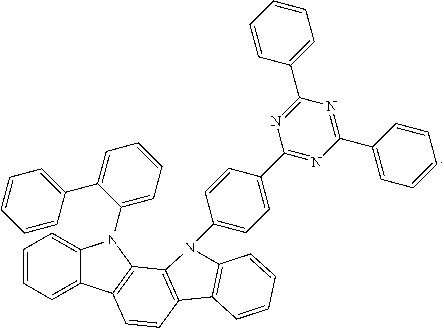 [SMILES: c1ccc(-c2nc(-c3ccccc3)nc(-c3ccc(-n4c5ccccc5c5ccc6c7ccccc7n(-c7ccccc7-c7ccccc7)c6c54)cc3)n2)cc1]

17. The display panel according to claim 14, wherein, the chemical structural formula of the first light-emitting host material is:

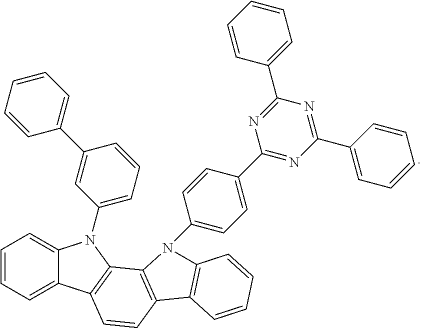 [SMILES: c1ccc(-c2cccc(-n3c4ccccc4c4ccc5c6ccccc6n(-c6ccc(-c7nc(-c8ccccc8)nc(-c8ccccc8)n7)cc6)c5c43)c2)cc1]

18. The display panel according to claim 12, wherein, the light-emitting layer is made of a first light-emitting host material, a second light-emitting host material and a phosphorescent dopant, and the barrier layer is made of the first light-emitting host material.

19. The display panel according to claim 18, wherein, a ratio of film thicknesses of the first light-emitting host material, the second light-emitting host material and the phosphorescent dopant is 5:5:1.

20. The display panel according to claim 18, wherein, the chemical structural formula of the second light-emitting host material is: 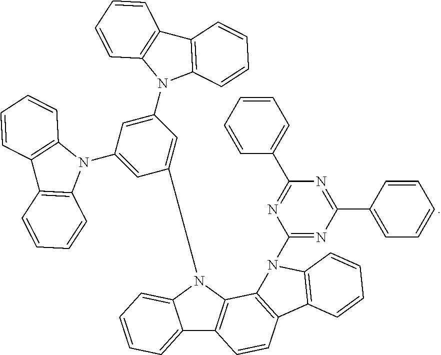 [SMILES: c1ccc(-c2nc(-c3ccccc3)nc(-n3c4ccccc4c4ccc5c6ccccc6n(-c6cc(-n7c8ccccc8c8ccccc87)cc(-n7c8ccccc8c8ccccc87)c6)c5c43)n2)cc1]
